(19) United States
(12) Patent Application Publication
(10) Pub. No.: US 2013/0112257 A1
(43) Pub. Date: May 9, 2013

(54) COMPOSITE ENCAPSULATION MATERIAL FOR PHOTOVOLTAIC DEVICES AND METHODS OF THEIR MANUFACTURE

(71) Applicants: Jed Emeron Isom, Arvada, CO (US); Scott Daniel Feldman-Peabody, Golden, CO (US)

(72) Inventors: Jed Emeron Isom, Arvada, CO (US); Scott Daniel Feldman-Peabody, Golden, CO (US)

(73) Assignee: PRIMESTAR SOLAR, INC., Arvada, CO (US)

(21) Appl. No.: 13/290,474

(22) Filed: Nov. 7, 2011

(51) Int. Cl. H01L 31/0203; H01L 31/02

(52) U.S. Cl. 136/256

(57) ABSTRACT

Thin film photovoltaic devices are generally provided. The thin film photovoltaic devices can include a transparent substrate that has a first volumetric thermal expansion coefficient; a thin film stack comprising a transparent conductive oxide layer, a photovoltaic heterojunction, and back contact layer; and, a composite encapsulation material on the back contact layer. The thin film stack is generally positioned between the transparent substrate and the composite encapsulation material. The composite encapsulation material can have a second volumetric thermal expansion coefficient that is within about +/−40% of the first volumetric thermal expansion coefficient of the transparent substrate.

### FIELD OF THE INVENTION

The subject matter disclosed herein relates generally to a composite back material for use in a photovoltaic device, along with their methods of deposition. More particularly, the subject matter disclosed herein relates to a composite back material for use in photovoltaic devices having a front substrate made from a specialty glass and their methods of manufacture.

### BACKGROUND OF THE INVENTION

Thin film solar modules are typically constructed with a front material (usually glass) and a back material (also usually glass) that are sealed together to protect the internal device while it is in service. The front material is ideally transparent to light (i.e., radiation energy) at the wavelengths corresponding to the energy conversion with minimal absorption and/or reflection in order to allow the maximum amount of available light to reach the underlying thin films. Many factors can affect the amount of absorption and/or reflection of the front material, such as the thickness of the front material, the type of material selected, etc. For example, reducing the thickness of the front material may lead to less absorption in the front material.

One material that is currently used in many thin film solar modules as both the front material and the back material is soda-lime glass. However, it has been found that soda-lime glass may not be able to withstand the processing temperatures associated with module formation, prompting a move to use more temperature-resistant specialty glasses, such as borosilicate glasses. Such specialty glasses tend to be more expensive than soda-lime glasses, prompting a push toward thinner glass use, to lessen material costs. Yet, reducing the thickness of such a front material can lead to unwanted side-effects, such as a loss in overall strength of the front material and an increased tendency toward overall module failure.

When the front material composition changes in its composition, its coefficient of thermal expansion (CTE) may also change. In a lamination of two planar substrates (i.e., the front material and the back material), if one of the planar substrates expands or contracts in response to a change in temperature more than the other planar substrate, stemming from a substantial difference between their respective coefficients of thermal expansion, the result is bowing or otherwise bending and flexing of the laminate. Thus, a laminate formed from a new front material composition without changing the back material may bow or otherwise flex out of its planar configuration in response to a temperature fluctuation due to a CTE mismatch between the new front material and the back material. This bowing can introduce additional stresses into the solar module, and can thus add a field reliability concern.

Ideally, the front substrate and the back substrate are formed from the same material, ensuring that their respective thermal expansion coefficients are substantially the same. However, certain front substrate materials made from specialty materials (e.g., borosilicate glass, etc.) may be cost-prohibitive for use as both the front substrate and the back substrate.

Thus, a need exists for a back material that can minimize any bowing in a thin film solar module, especially in the front substrate, upon experiencing a temperature fluctuation.

### BRIEF DESCRIPTION OF THE INVENTION

Aspects and advantages of the invention will be set forth in part in the following description, or may be obvious from the description, or may be learned through practice of the invention.

Thin film photovoltaic devices are generally provided. According to one embodiment, the thin film photovoltaic devices can include a transparent substrate that has a first volumetric thermal expansion coefficient; a thin film stack comprising a transparent conductive oxide layer, a photovoltaic heterojunction, and back contact layer; and, a composite encapsulation material on the back contact layer. The thin film stack is generally positioned between the transparent substrate and the composite encapsulation material. The composite encapsulation material can have a second volumetric thermal expansion coefficient that is within about +/−40% of the first volumetric thermal expansion coefficient of the transparent substrate (e.g., within about +/−25% of the first volumetric thermal expansion coefficient of the transparent substrate, or within about +/−10% of the first volumetric thermal expansion coefficient of the transparent substrate), even though the composite encapsulation material and the transparent substrate are constructed from different materials.

In one particular embodiment, a back substrate can also be attached to the composite encapsulation material. For example, the composite encapsulation material can be positioned between the thin film stack and the back substrate. Alternatively, the back substrate can be positioned between the thin film stack and the composite encapsulation material. Additionally, an adhesive layer may, in certain embodiments, be positioned somewhere between the thin film stack and the composite encapsulation material.

The thin film photovoltaic device, in another embodiment, can include a transparent substrate that has a first volumetric thermal expansion coefficient; a thin film stack comprising a transparent conductive oxide layer, a photovoltaic heterojunction, and back contact layer; and, a composite encapsulation material on the back contact layer. The thin film stack is generally positioned between the transparent substrate and the composite encapsulation material. The composite encapsulation material can have a second volumetric thermal expansion coefficient that is within about +/−3.5 from the first volumetric thermal expansion coefficient of the transparent substrate (e.g., within about +/−2.0), even though the composite encapsulation material and the transparent substrate are constructed from different materials.

The thin film photovoltaic device, in another embodiment, can include transparent substrate, a thin film stack, and a composite encapsulation material. The transparent substrate generally can comprise a first material and can have a thickness (i.e., a “front thickness”) of about 0.5 mm to about 2.5 mm defined from its front surface to its inner surface. The thin film stack can include a transparent conductive oxide layer, a photovoltaic heterojunction, and back contact layer, along with other layers for forming a PV device. The encapsulation material can be laminated to the transparent substrate such that the thin film stack is positioned between the transparent substrate and the composite encapsulation material. The composite encapsulation material and the transparent substrate are constructed from different materials. The composite encapsulation material can have a back thickness and a volumetric thermal expansion coefficient to limit bowing in the transparent substrate upon lamination such that a maximum peak-to-trough distance defined by the front surface of the transparent substrate is about 100% or less than the front thickness.

Methods are also generally provided for forming such photovoltaic devices.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures, in which:

FIG. 1 shows a general schematic of a cross-sectional view of an exemplary thin film photovoltaic device including a composite back material;

FIG. 2 shows a general schematic of a cross-sectional view of an exemplary thin film photovoltaic device including a composite back material and a back glass;

FIG. 3 shows a general schematic of a cross-sectional view of another exemplary thin film photovoltaic device including a composite back material and a back glass;

FIG. 4 shows a general schematic of a cross-sectional view of yet another exemplary thin film photovoltaic device including a composite back material and a back glass;

FIG. 5 shows a general schematic of a cross-sectional view of an exemplary thin film photovoltaic device including a back glass and a composite back material that defines a plurality of rib elements;

FIG. 6 shows a general schematic of a cross-sectional view of an exemplary thin film photovoltaic device including a composite back material that defines a plurality of rib elements;

FIG. 7 shows a general schematic of a cross-sectional view of another exemplary thin film photovoltaic device including a back glass and a composite back material that defines a plurality of rib elements;

FIG. 8 shows a general schematic of a cross-sectional view of another exemplary thin film photovoltaic device including a composite back material that defines a plurality of rib elements;

FIG. 9 shows a general schematic of a cross-sectional view of an exemplary thin film stack for use in any of the devices shown in FIGS. 1-8 and 11-12;

FIG. 10 shows a general schematic of a cross-sectional view of an exemplary transparent substrate defining maximum peak-to-trough distance in its front surface;

FIG. 11 shows a general schematic of a cross-sectional view of an exemplary thin film photovoltaic device including a back glass and a composite back material that defines a plurality of rib elements, where at least two rib elements are oriented to interest each other; and,

FIG. 12 shows a general schematic of a cross-sectional view of an exemplary thin film photovoltaic device including a back glass and a composite back material that defines a plurality of rib elements, where at least two rib elements are oriented to interest each other.

Repeat use of reference characters in the present specification and drawings is intended to represent the same or analogous features or elements.

### DEFINITIONS

In the present disclosure, when a layer is being described as “on” or “over” another layer or substrate, it is to be understood that the layers can either be directly contacting each other or have another layer or feature between the layers, unless expressly stated to the contrary. Thus, these terms are simply describing the relative position of the layers to each other and do not necessarily mean “on top of” since the relative position above or below depends upon the orientation of the device to the viewer. Additionally, although the invention is not limited to any particular film thickness, the term “thin” describing any film layers of the photovoltaic device generally refers to the film layer having a thickness less than about 10 micrometers (“microns” or “μm”).

As used herein, the coefficient of thermal expansion (α) generally describes the tendency of matter to change in volume in response to a change in temperature. Thus, the coefficient of thermal expansion is the fractional change in length or volume of a material per degree of temperature change. In the case of solid materials (including glass), the pressure does not appreciably affect the size of an object, and so, it's not necessary to specify that the pressure be held constant. Two types of coefficients of thermal expansion are discussed in this disclosure: the volumetric thermal expansion coefficient (vₛ) and the linear thermal expansion coefficient (aₗₗ).

The volumetric thermal expansion coefficient relates the change in a material's size to a change in temperature. Ignoring pressure, as discussed above, the volumetric thermal expansion coefficient calculated according to Formula 1:

$${a}_{V} = \frac{1}{V} \frac{d V}{d T} \qquad Formula 1$$

where V is the volume of the material, and do/dot is the rate of change of that volume with temperature.

The linear thermal expansion coefficient relates the change in a material's linear dimensions to a change in temperature. It is the fractional change in length per degree of temperature change. Ignoring pressure, as discussed above, the linear thermal expansion coefficient can be calculated according to the formula

$${a}_{L} = \frac{1}{L} \frac{d L}{d T}$$

where L is the linear dimension (e.g. length) and dL/dT is the rate of change of that linear dimension per unit change in temperature.

In the present application, it is assumed that the thermal expansion coefficient does not change much over the change in temperature ΔT. As such, the thermal expansion coefficient values are given as at 20° C. All values of thermal expansion coefficients given herein are in units of 10⁻⁶/° C. unless otherwise specified.

It is to be understood that the ranges and limits mentioned herein include all ranges located within the prescribed limits (i.e., subranges). For instance, a range from about 100 to about 200 also includes ranges from 110 to 150, 170 to 190, 153 to 162, and 145.3 to 149.6. Further, a limit of up to about 7 also includes a limit of up to about 5, up to 3, and up to about 4.5, as well as ranges within the limit, such as from about 1 to about 5, and from about 3.2 to about 6.5.

### DETAILED DESCRIPTION OF THE INVENTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

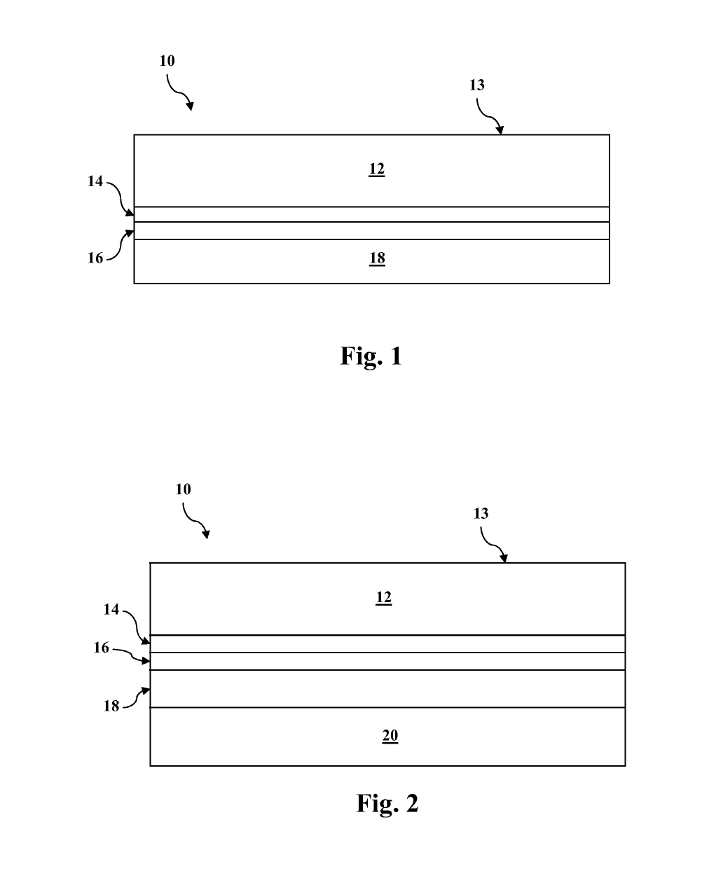

Thin film photovoltaic devices are generally disclosed having a thin film stack between a transparent substrate (serving as the front material) and a composite encapsulation material (serving as the back material). FIG. 1 shows a cross-section of an exemplary thin-film photovoltaic device 10. The device 10 is shown including a transparent substrate 12 (e.g., a glass substrate), a thin film stack 14, an optional adhesive layer 16, and a composite encapsulation material 18.

The coefficient of thermal expansion (e.g., the volumetric thermal expansion coefficient and/or the linear thermal expansion coefficient) of the transparent substrate 12 and the composite encapsulation material 18 can be substantially similar. Thus, the composite encapsulation material 18 can help to minimize bowing of the device 20, and particularly the transparent substrate 12, upon experiencing changes in temperature. The presence of the composite encapsulation material 18 is particularly advantageous when the material of the transparent substrate 12 is too expensive for use as both the transparent substrate 12 and the composite encapsulation material 18 (e.g., as in the case where a transparent substrate 12 constructed from borosilicate glass).

For example, the transparent substrate 12 can have a first volumetric thermal expansion coefficient, while the composite encapsulation material 18 has a second volumetric thermal expansion coefficient that is within about +/−40% of the first volumetric thermal expansion coefficient of the transparent substrate 12. In one particular embodiment, the second volumetric thermal expansion coefficient of the composite encapsulation material 18 can be within about +/−25% of the first volumetric thermal expansion coefficient of the transparent substrate 12 (e.g., within about +/−10% of the first volumetric thermal expansion coefficient of the transparent substrate). For example, the second volumetric thermal expansion coefficient of the composite encapsulation material 18 can be about 5% to about 25% of the first volumetric thermal expansion coefficient of the transparent substrate 12 (e.g., about 5% to about 10% of the first volumetric thermal expansion coefficient of the transparent substrate 12) or about −5% to about −25% of the first volumetric thermal expansion coefficient of the transparent substrate 12 (e.g., about −5% to about −10% of the first volumetric thermal expansion coefficient of the transparent substrate 12). Alternatively stated, the volumetric thermal expansion differential may be within about +/−3.5 from an absolute value perspective, such as about +/−2.0.

Similarly, the transparent substrate 12 can have a first linear thermal expansion coefficient, while the composite encapsulation material 18 has a linear volumetric thermal expansion coefficient that is within about +/−40% of the first linear thermal expansion coefficient of the transparent substrate 12. In one particular embodiment, the second linear thermal expansion coefficient of the composite encapsulation material 18 can be within about +/−25% of the first linear thermal expansion coefficient of the transparent substrate 12 (e.g., within about +/−10% of the first linear thermal expansion coefficient of the transparent substrate). For example, the second linear expansion coefficient of the composite encapsulation material 18 can be about 5% to about 25% of the first linear thermal expansion coefficient of the transparent substrate 12 (e.g., about 5% to about 10% of the first linear thermal expansion coefficient of the transparent substrate 12) or about −5% to about −25% of the first linear thermal expansion coefficient of the transparent substrate 12 (e.g., about −5% to about −10% of the first linear thermal expansion coefficient of the transparent substrate 12). Alternatively stated, the linear thermal expansion differential may further be within about +/−3.5 from an absolute value perspective, such as about +/−2.0.

The use of such a composite encapsulation material can be particularly advantageous in conjunction with a transparent substrate 12 that has a coefficient of thermal expansion that is not well-matched to a standard back substrate (e.g., soda lime glass). For example, if the transparent substrate 12 comprises borosilicate glass, the transparent substrate 12 can have a volumetric thermal expansion coefficient of about 9.5 to about 10.5 at 20° C. (e.g., about 9.8 to about 10) and a linear thermal expansion coefficient of about 3 to about 3.5 at 20° C. (e.g., about 3.2 to about 3.4). Thus, such transparent substrates 12 comprising borosilicate glass have a large difference in the thermal expansion coefficient with soda-lime glass (which has a volumetric thermal expansion coefficient of about 25.5 at 20° C. and a linear thermal expansion coefficient of about 8.5 at 20° C.). If a soda-lime glass is used as an encapsulation substrate, as is currently typical, an unwanted thermal expansion mismatch between the front and back substrates results.

In one embodiment, the transparent substrate 12 can be employed as a “superstrate,” as it is the substrate on which the subsequent layers are formed, even though it faces upward to the radiation source (e.g., the sun) when the photovoltaic device 10 is in use. The transparent substrate 12 can be a high-transmission glass (e.g., high transmission borosilicate glass), low-iron float glass, or other highly transparent glass material. The glass is generally thick enough to provide support for the subsequent film layers, and is substantially flat enough, e.g., to provide a good surface for forming the subsequent film layers and to facilitate the appropriate laser scribing thereof. In one embodiment, the glass substrate 12 can be a borosilicate glass with a thickness of about 0.5 mm to about 2.5 mm, such as about 0.7 mm to about 1.3 mm.

As stated, the composite encapsulation material 18 can be selected based on the composition of the transparent substrate 12 in order to match their respective coefficients of thermal expansion. Additionally, the composite encapsulation material 18 can be electrically inactive (e.g., an electrical insulator and/or a dielectric), so as to not interfere with the performance of the device 10. In one particular embodiment, the composite encapsulation material can include a two or three dimensional web of fibers (e.g., carbon fibers, fiberglass fibers, para-aramid synthetic fibers, or a combination thereof) carried within a matrix material (e.g., polymer, glass, ceramic, carbon, etc.). Particles and other fillers can, additionally or alternatively to the fibers, be included in the composite encapsulation material 18 to adjust the coefficient of thermal expansion of the composite encapsulation material 18. Further alternatively, the filler could take on a structural form, such as a honeycomb, which extends throughout the composite. Meanwhile, the matrix material may be chosen, in part, to achieve the desired coefficient of thermal expansion, mechanical durability, and/or chemical durability. In fact, the matrix material may be chosen particularly to ensure that the composite encapsulation material 18 can endure fail-safe conditions, such as might exist during a fire.

The desired coefficient of thermal expansion of the composite encapsulation material 18 may be achieved, for example, by using low-expansion fibers such as fiberglass and/or by employing a weave or layering pattern that ultimately produces a desired net coefficient of thermal expansion within the bulk of the composite encapsulation material 18. This may create internal stress within the composite bulk material, but the composite part as a whole will have a CTE that closely matches that of the substrate 12. This can be accomplished by known means (e.g., material choice; composite structure, see Mechanics of Fibrous Composites by Carl T. Herakovich).

In one embodiment, the composite encapsulation material 18 can include a film forming binder that can aid in the adherence and bonding mechanism of the device 10. For example, the film forming binder can include, but is not limited to, ethylene vinyl acetate (EVA), epoxy resins, an ionomer, or copolymers thereof or mixtures thereof. When including such a binder, the adhesive layer 16 may be omitted from certain embodiments of the device 10, if desired, due to the adhesive qualities of the binder in the composite encapsulation material 18.

The process of forming the binder generally involves a lamination process, which may include placing the substrate, binder and encapsulation material at a high temperature (e.g., in the range of about 100° C. to about 170° C.) while the binder cures, crosslinks, etc. to form the permanent bond between the substrate and the encapsulation material. This permanent bond can help seal the device from the elements over its expected lifetime in the field. The adhesive layer 16 can be included in the device 10, if desired, to aid in the lamination of the transparent substrate 12, the thin film stack 14, and the composite encapsulation material 18 together. The adhesive layer 16 can include, for example, ethylene vinyl acetate (EVA), epoxy resins, an ionomer, an acrylic adhesive, etc. or mixtures thereof.

In one embodiment, the composite encapsulation material 18 can have a strength and/or environmental impermeability sufficient to act alone in the device 10 as the back support, without the presence of an additional back substrate. However, in certain embodiments, a back substrate can be included in the device 10 in addition to the composite encapsulation material 18.

FIGS. 2-4 show embodiments where the device 10 also includes a back substrate 20 in combination with the transparent substrate 12, the thin film stack 14, the adhesive layer 16, and the composite encapsulation material 18, in various configurations. In these embodiments, the composite encapsulation material 18 may serve as a support structure while the back substrate serves as an environmental seal.

Referring to FIGS. 2-3, the device 10 shown includes the composite encapsulation material 18 positioned between the thin film stack 14 and the back substrate 20. In the embodiment shown in FIG. 2, the adhesive layer 16 is positioned between the thin film stack 14 and the composite encapsulation material 18. Alternatively, the embodiment shown in FIG. 3 has the adhesive layer 16 positioned between the composite encapsulation material 18 and the back substrate 20.

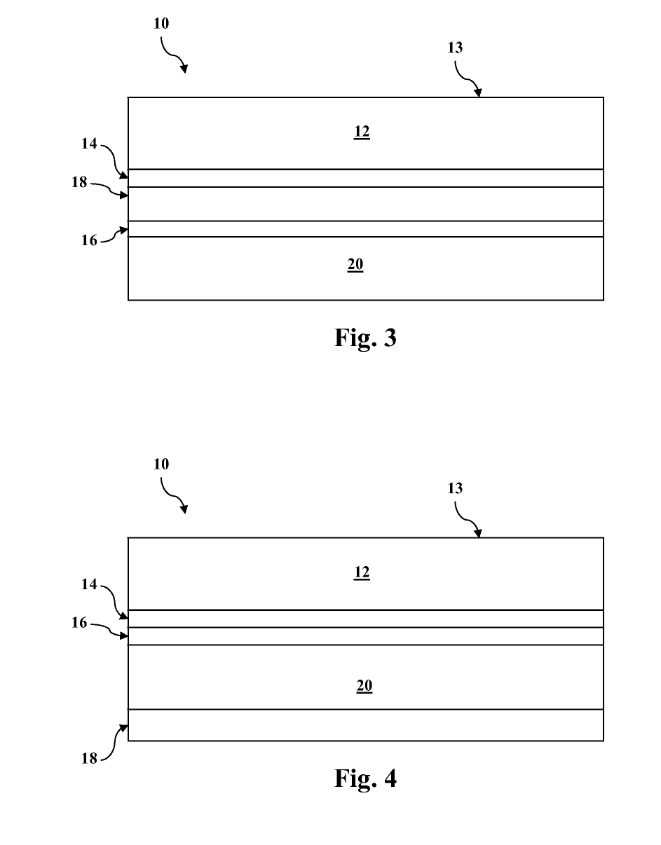

In the embodiment shown in FIG. 4, shows an embodiment of the device 10 where the back substrate 20 is positioned between the thin film stack 14 and the composite encapsulation material 18, with the adhesive layer 16 positioned between the thin film stack 14 and the back substrate 20.

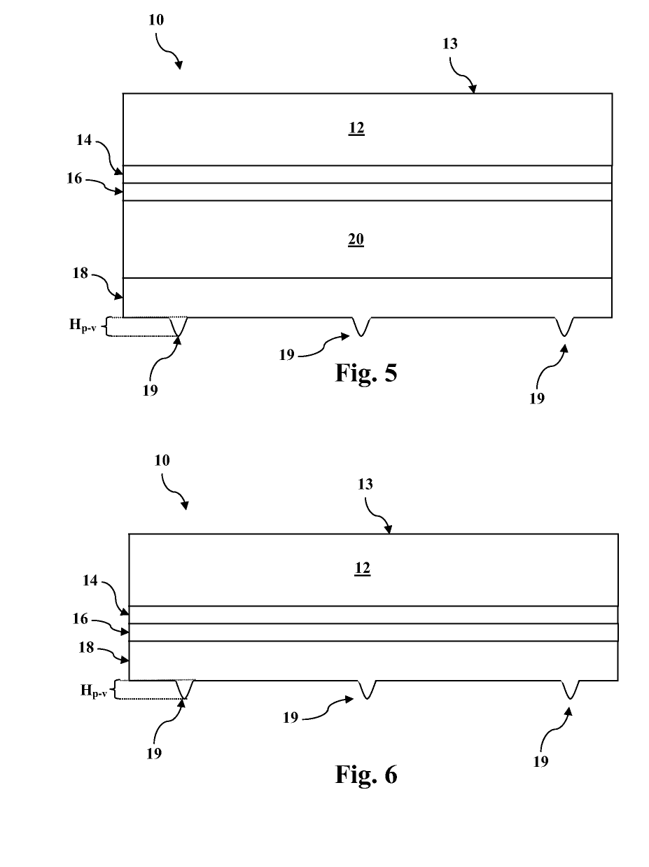

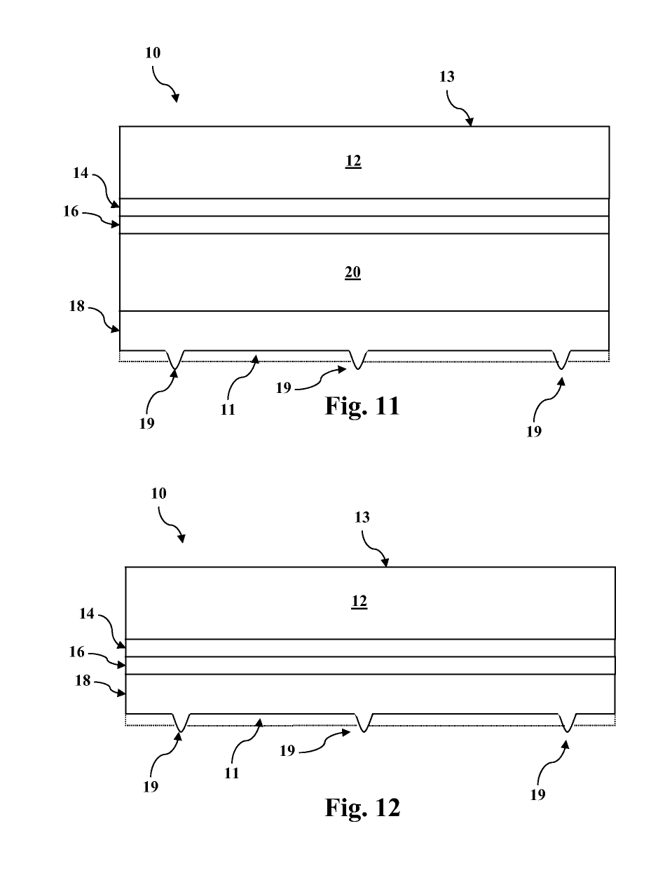

FIGS. 5-8 show embodiments where the composite encapsulation material 18 defines at least one rib element 19 on the device 10. The rib elements 19 can provide additional strength and stiffness, particularly in their direction of orientation, through beam-like support of the device 10, and may aid in the cooling of the device, due to the increased amount of radiative surface provided thereby. For example, the rib element 19 can extend entirely across a length or width of the composite encapsulation material 18 (e.g., in a direction that is parallel with the length of the device 10). The rib elements 19 can be formed through molding or other deformation techniques during or after the formation of the composite encapsulation material 18. As shown, the composite encapsulation material 18 is positioned such that the rib elements 19 extend away from the thin film stack 14 of the device 10. It is to be understood that the layout of the rib elements 19 can take any of a variety of other forms, including, for example, a honeycomb structure or a series of crossing ribs, each of which can help provide two-dimensional strengthening. For example, FIGS. 11-12, which are similar to FIGS. 5-6, shown that a cross-sectional rib element 11 that intersects the rib elements 19. A shown, the cross-sectional rib element 11 is substantially perpendicular to the rib elements 19; however, it is understood that the plurality of rib elements 19 can form any suitable pattern and can have rib elements oriented in any direction or combination of directions.

In the embodiments of FIGS. 5-8, the bulk coefficient of thermal expansion of the composite encapsulation material 18 does not necessarily have to substantially match (i.e., within +/−40%) the coefficient of thermal expansion of the transparent substrate 12, since the ribs 19 can help mechanically inhibit bending of the device 10.

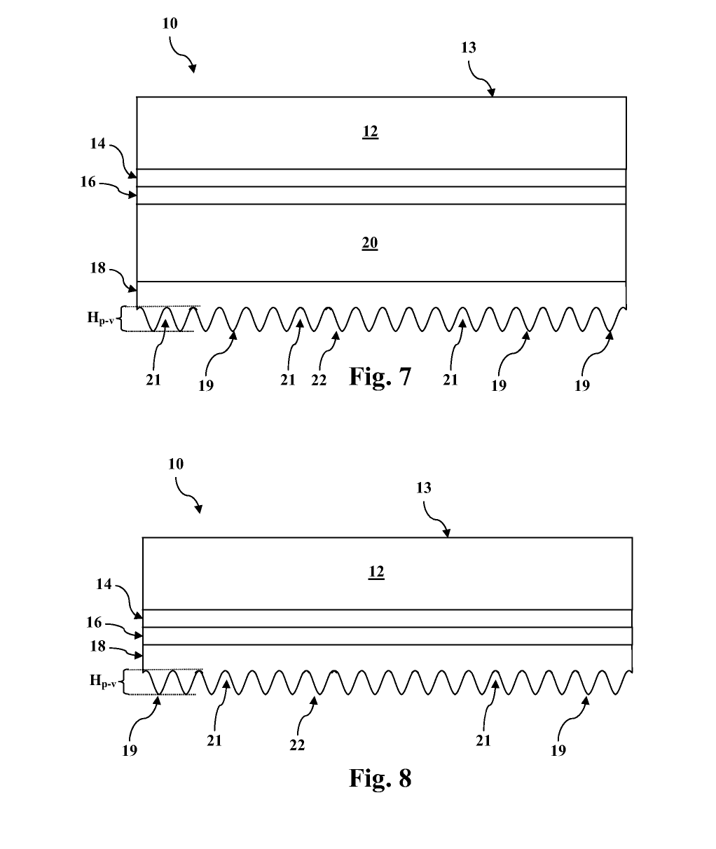

Although shown defining three rib elements 19 in the embodiments shown in FIGS. 5-6, any number of rib elements 19 can be present in the device 10 (i.e., at least one rib element 19 can be defined by the composite encapsulation substrate 18). For example, FIGS. 7-8 depict embodiments where a plurality of rib elements 19 is defined by the composite encapsulation substrate 18. As shown, each rib element 19 can be oriented parallel to each other. In these embodiments, each adjacent rib element 19 is separated by a corresponding valley 21. As shown, the plurality of rib elements 18 can form a continuous wave 22 extending across the composite encapsulation material.

The rib element 19 can define a rib height (Hₚ₋ᵥ), as defined in the z-direction as the distance from the valley 21 to the peak of the rib element 19, as shown in FIGS. 5-6. For example, in one embodiment, the rib elements 19 can have a rib height (Hₚ₋ᵥ) of about 0.1 mm to about 20 mm, such as about 0.5 mm to about 10 mm. The width and spacing of the rib elements 19 can be varied as desired, and may be selected based on the material selected for construction of the encapsulation substrate 18.

As stated, through the use of the composite encapsulation material 18 and/or the rib elements 19, the amount of bending and/or deformation in the transparent substrate 12 can be minimized. One way to quantify the amount of bending and/or deformation in the transparent substrate 12 is the maximum peak-to-trough distance present in the transparent substrate 12. Referring to FIG. 10, the maximum peak-to-trough distance (Dₚ₋ₜ) is calculated by measuring the distance in the z-direction, which is perpendicular to the x, y plane of the transparent substrate 12, from the highest peak 30 to the lowest trough 32 in the outer surface 13 of the transparent substrate. Although the configuration shown in FIG. 10 correlates to that of FIG. 1, it is understood that the peak-to-trough distance of the transparent substrate 12 applies to any device 10 configuration (e.g., any of FIGS. 1-8). Also, it is noted that the inner surface of the transparent substrate 12 contacting the thin film stack 14 may have a shape that generally corresponds to the outer surface 13 since the thickness of the transparent substrate 12 in the z-direction can be substantially uniform throughout its x, y plane in most embodiments, although not shown in FIG. 10.

The maximum peak-to-trough distance that is acceptable for a particular substrate can vary depending on the actual size of the device 10 in the x, y direction, the thickness of the transparent substrate 12 in the z-direction, etc. In most embodiments, the maximum peak-to-trough distance can be about 100% or less of the thickness of the transparent substrate 12 (e.g., about 50% or less). In certain embodiments, the maximum peak-to-trough distance can be about 1% to about 50% of the thickness of the transparent substrate 12 (e.g., about 5% to about 25%).

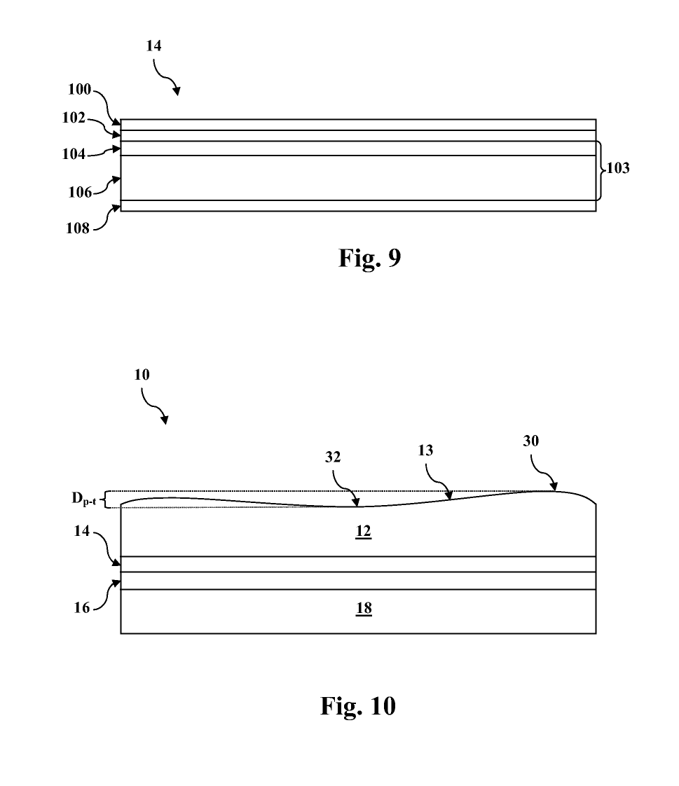

As depicted in FIG. 9, the thin film stack 14 can generally include a transparent conductive oxide layer 100 (a TCO layer), an optional resistive transparent buffer layer 102 (a RTB layer), a photovoltaic heterojunction 103, and back contact layer 108. As shown, the photovoltaic heterojunction 103 is formed from an n-type window layer 104 and an absorber layer 106. In one particular embodiment, the absorber layer 106 can include cadmium telluride (i.e., a cadmium telluride layer). In this embodiment, the n-type window layer 104 can include cadmium sulfide (i.e., a cadmium sulfide layer). Although described as a cadmium telluride thin film stack 14 in the following description of FIG. 9, the composite encapsulation material 18 can be included in any type of thin film photovoltaic device 10.

Generally, the TCO layer 100 is positioned on the transparent substrate 12 of the exemplary device 10 in FIGS. 1-8. The TCO layer 100 allows light to pass through with minimal absorption while also allowing electric current produced by the thin film stack 14 to travel sideways to opaque metal conductors (not shown). For instance, the TCO layer 100 can have a sheet resistance less than about 30 ohm per square, such as from about 4 ohm per square to about 20 ohm per square (e.g., from about 8 ohm per square to about 15 ohm per square). The TCO layer 100 can generally include at least one conductive oxide, such as tin oxide, zinc oxide, indium tin oxide, zinc stannate, cadmium stannate, or mixtures thereof. Additionally, the TCO layer 100 can include other conductive, transparent materials. The TCO layer 100 can also include dopants (e.g., fluorine, tin, etc.) and other materials, as desired.

The TCO layer 100 can be formed by sputtering, chemical vapor deposition, spray pyrolysis, or any other suitable deposition method. In one particular embodiment, the TCO layer 100 can be formed by sputtering (e.g., DC sputtering or RF sputtering) on the glass substrate 12. For example, a cadmium stannate layer can be formed by sputtering a hot-pressed target containing stoichiometric amounts of SnO₂ and CdO onto the glass substrate 12 in a ratio of about 1 to about 2. The cadmium stannate can alternatively be prepared by using cadmium acetate and tin (II) chloride precursors by spray pyrolysis. In certain embodiments, the TCO layer 100 can have a thickness between about 0.1 μm and about 1 μm, for example from about 0.1 μm to about 0.5 μm, such as from about 0.25 μm to about 0.35 μm.

An optional resistive transparent buffer layer 102 (RTB layer) is shown on the TCO layer 100 in the thin film stack 14 of FIG. 9. The RTB layer 102 is generally more resistive than the TCO layer 100 and can help protect the thin film stack 14 from chemical interactions between the TCO layer 100 and the subsequent layers. For example, in certain embodiments, the RTB layer 102 can have a sheet resistance that is greater than about 1000 ohms per square, such as from about 10 kOhms per square to about 1000 MOhms per square. The RTB layer 102 can also have a wide optical bandgap (e.g., greater than about 2.5 eV, such as from about 2.7 eV to about 3.5 eV).

Without wishing to be bound by a particular theory, it is believed that the presence of the RTB layer 102 between the TCO layer 100 and the photovoltaic heterjunction 103 can allow for a relatively thin n-type window layer 104 to be included in the thin film stack 14 by reducing the possibility of interface defects (i.e., “pinholes” in the n-type window layer 104) creating shunts between the TCO layer 100 and the absorber layer 106. The RTB layer 102 can include, for instance, a combination of zinc oxide (ZnO) and tin oxide (SnO₂), which can be referred to as a zinc tin oxide layer (“ZTO”). In one particular embodiment, the RTB layer 102 can include more tin oxide than zinc oxide. For example, the RTB layer 102 can have a composition with a stoichiometric ratio of ZnO/SnO₂ between about 0.25 and about 3, such as in about an one to two (1:2) stoichiometric ratio of tin oxide to zinc oxide. The RTB layer 102 can be formed by sputtering, chemical vapor deposition, spray-pyrolysis, or any other suitable deposition method. In one particular embodiment, the RTB layer 102 can be formed by sputtering (e.g., DC sputtering or RF sputtering) on the TCO layer 100. For example, the RTB layer 102 can be deposited using a DC sputtering method by applying a DC current to a metallic source material (e.g., elemental zinc, elemental tin, or a mixture thereof) and sputtering the metallic source material onto the TCO layer 100 in the presence of an oxidizing atmosphere (e.g., O₂ gas). When the oxidizing atmosphere includes oxygen gas (i.e., O₂), the atmosphere can be greater than about 95% pure oxygen, such as greater than about 99%.

In certain embodiments, the RTB layer 102 can have a thickness between about 0.075 μm and about 1 μm, for example from about 0.1 μm to about 0.5 μm. In particular embodiments, the RTB layer 102 can have a thickness between about 0.08 μm and about 0.2 μm, for example from about 0.1 μm to about 0.15 μm.

A cadmium sulfide layer 104 is shown on RTB layer 102 of the exemplary thin film stack 14. The cadmium sulfide layer 104 is a n-type window layer that generally includes cadmium sulfide (CdS) but may also include other materials, such as zinc sulfide, cadmium zinc sulfide, etc., and mixtures thereof as well as dopants and other impurities. In one particular embodiment, the cadmium sulfide layer may include oxygen up to about 25% by atomic percentage, for example from about 5% to about 20% by atomic percentage. The cadmium sulfide layer 104 can have a wide band gap (e.g., from about 2.25 eV to about 2.5 eV, such as about 2.4 eV) in order to allow most radiation energy (e.g., solar radiation) to pass. As such, the cadmium sulfide layer 104 is considered a transparent layer in the thin film stack 14.

The cadmium sulfide layer 104 can be formed by sputtering, chemical vapor deposition, chemical bath deposition, and other suitable deposition methods. In one particular embodiment, the cadmium sulfide layer 104 can be formed by sputtering (e.g., direct current (DC) sputtering or radio frequency (RF) sputtering) on the RTB layer 102. Sputtering deposition generally involves ejecting material from a target, which is the material source, and depositing the ejected material onto the substrate to form the film. DC sputtering generally involves applying a current to a metal target (i.e., the cathode) positioned near the substrate (i.e., the anode) within a sputtering chamber to form a direct-current discharge. The sputtering chamber can have a reactive atmosphere (e.g., an oxygen atmosphere, nitrogen atmosphere, fluorine atmosphere) that forms a plasma field between the metal target and the substrate. The pressure of the reactive atmosphere can be between about 1 mTorr and about 20 mTorr for magnetron sputtering. When metal atoms are released from the target upon application of the voltage, the metal atoms can react with the plasma and deposit onto the surface of the substrate. For example, when the atmosphere contains oxygen, the metal atoms released from the metal target can form a metallic oxide layer on the substrate. The current applied to the source material can vary depending on the size of the source material, size of the sputtering chamber, amount of surface area of substrate, and other variables. In some embodiments, the current applied can be from about 2 amps to about 20 amps. Conversely, RF sputtering generally involves exciting a capacitive discharge by applying an alternating-current (AC) or radio-frequency (RF) signal between the target (e.g., a ceramic source material) and the substrate. The sputtering chamber can have an inert atmosphere (e.g., an argon atmosphere) having a pressure between about 1 mTorr and about 20 mTorr.

Due to the presence of the RTB layer 102, the cadmium sulfide layer 104 can have a thickness that is less than about 0.1 μm, such as between about 10 nm and about 100 nm, such as from about 50 nm to about 80 nm, with a minimal presence of pinholes between the TCO layer 100 and the cadmium sulfide layer 104. Additionally, a cadmium sulfide layer 104 having a thickness less than about 0.1 μm reduces any absorption of radiation energy by the cadmium sulfide layer 104, effectively increasing the amount of radiation energy reaching the underlying cadmium telluride layer 106.

A cadmium telluride layer 106 is shown on the cadmium sulfide layer 104 in the exemplary thin film stack 14. The cadmium telluride layer 106 is a p-type layer that generally includes cadmium telluride (CdTe) but may also include other materials. As the p-type layer in the thin film stack 14, the cadmium telluride layer 106 is the photovoltaic layer that interacts with the cadmium sulfide layer 104 (i.e., the n-type layer) to produce current from the adsorption of radiation energy by absorbing the majority of the radiation energy passing into the thin film stack 14 due to its high absorption coefficient and creating electron-hole pairs. For example, the cadmium telluride layer 106 can generally be formed from cadmium telluride and can have a bandgap tailored to absorb radiation energy (e.g., from about 1.4 eV to about 1.5 eV, such as about 1.45 eV) to create the maximum number of electron-hole pairs with the highest electrical potential (voltage) upon absorption of the radiation energy. Electrons may travel from the p-type side (i.e., the cadmium telluride layer 106) across the junction to the n-type side (i.e., the cadmium sulfide layer 104) and, conversely, holes may pass from the n-type side to the p-type side. Thus, the p-n junction formed between the cadmium sulfide layer 104 and the cadmium telluride layer 106 forms a diode in which the charge imbalance leads to the creation of an electric field spanning the photovoltaic heterojunction 103. Conventional current is allowed to flow in only one direction and separates the light induced electron-hole pairs.

The cadmium telluride layer 106 can be formed by any known process, such as vapor transport deposition, chemical vapor deposition (CVD), spray pyrolysis, electro-deposition, sputtering, close-space sublimation (CSS), etc. In one particular embodiment, the cadmium sulfide layer 104 is deposited by sputtering and the cadmium telluride layer 106 is deposited by close-space sublimation. In particular embodiments, the cadmium telluride layer 106 can have a thickness between about 0.1 μm and about 10 μm, such as from about 1 μm and about 5 μm. In one particular embodiment, the cadmium telluride layer 106 can have a thickness between about 1.5 μm and about 4 μm, such as about 2 μm to about 3 μm.

A series of post-forming treatments can be applied to the exposed surface of the cadmium telluride layer 106. These treatments can tailor the functionality of the cadmium telluride layer 106 and prepare its surface for subsequent adhesion to the back contact layer(s) 108. For example, the cadmium telluride layer 106 can be annealed at elevated temperatures (e.g., from about 350° C. to about 500° C., such as from about 375° C. to about 425° C.) for a sufficient time (e.g., from about 1 to about 40 minutes) to create a quality p-type layer of cadmium telluride. Without wishing to be bound by theory, it is believed that annealing the cadmium telluride layer decreases the deep-defect density and makes the CdTe layer more p-type. Additionally, the cadmium telluride layer 106 can recrystallize and undergo grain regrowth during annealing.

Annealing the cadmium telluride layer 106 can be carried out in the presence of cadmium chloride in order to dope the cadmium telluride layer 106 with chloride ions. For example, the cadmium telluride layer 106 can be washed with an aqueous solution containing cadmium chloride then annealed at the elevated temperature (e.g., via heating the photovoltaic heterojunction to a treatment temperature of about 380° C. to about 430° C.).

In one particular embodiment, after annealing the cadmium telluride layer 106 in the presence of cadmium chloride, the surface can be washed to remove any cadmium oxide formed on the surface. This surface preparation can leave a Te-rich surface on the cadmium telluride layer 106 by removing oxides from the surface, such as CdO, CdTeO₃, CdTe₂O₅, etc. For instance, the surface can be washed with a suitable solvent (e.g., ethylenediamine also known as 1,2diaminoethane or “DAE”) to remove any cadmium oxide from the surface.

Additionally, copper can be added to the cadmium telluride layer 106. Along with a suitable etch, the addition of copper to the cadmium telluride layer 106 can form a surface of copper-telluride on the cadmium telluride layer 106 in order to obtain a low-resistance electrical contact between the cadmium telluride layer 106 (i.e., the p-type layer) and the back contact layer(s). Specifically, the addition of copper can create a surface layer of cuprous telluride (Cu₂Te) between the cadmium telluride layer 106 and the back contact layer 108 and/or can create a Cu-doped CdTe layer. Thus, the Te-rich surface of the cadmium telluride layer 106 can enhance the collection of current created by the thin film stack 14 through lower resistivity between the cadmium telluride layer 106 and the back contact layer 108.

Copper can be applied to the exposed surface of the cadmium telluride layer 106 by any process. For example, copper can be sprayed or washed on the surface of the cadmium telluride layer 106 in a solution with a suitable solvent (e.g., methanol, water, or the like, or combinations thereof) followed by annealing. In particular embodiments, the copper may be supplied in the solution in the form of copper chloride, copper iodide, or copper acetate. The annealing temperature is sufficient to allow diffusion of the copper ions into the cadmium telluride layer 106, such as from about 125° C. to about 300° C. (e.g. from about 150° C. to about 250° C.) for about 5 minutes to about 30 minutes, such as from about 10 to about 25 minutes.

A back contact layer 108 is shown on the cadmium telluride layer 106. The back contact layer 108 generally serves as the back electrical contact, in relation to the opposite, TCO layer 100 serving as the front electrical contact. The back contact layer 108 is suitably made from one or more highly conductive materials, such as elemental nickel, chromium, copper, tin, silver, or alloys or mixtures thereof. Additionally, the back contact layer 108 can be a single layer or can be a plurality of layers. In one particular embodiment, the back contact layer 108 can include graphite, such as a layer of carbon deposited on the p-layer followed by one or more layers of metal, such as the metals described above. The back contact layer 108, if made of or comprising one or more metals, is suitably applied by a technique such as sputtering or metal evaporation. If it is made from a graphite and polymer blend, or from a carbon paste, the blend or paste is applied to the semiconductor device by any suitable method for spreading the blend or paste, such as screen printing, spraying or by a “doctor” blade. After the application of the graphite blend or carbon paste, the device can be heated to convert the blend or paste into the conductive back contact layer. A carbon layer, if used, can be from about 0.1 μm to about 10 μm in thickness, for example from about 1 μm to about 5 μm. A metal layer of the back contact, if used for or as part of the back contact layer 108, can be from about 0.1 μm to about 1.5 μm in thickness.

Other thin film layers may also be present in the thin film stack 14. For example, index matching layers can be positioned between the transparent conductive oxide layer 100 and the transparent substrate 14. Additionally, an oxygen getter layer (e.g., comprising alumina) can be positioned between the transparent conductive oxide layer 100 and the resistive transparent buffer layer 102.

Other components (not shown) can be included in the exemplary device 10, such as buss bars, external wiring, laser etches, etc. For example, when the device 10 forms a photovoltaic cell of a photovoltaic module, a plurality of photovoltaic cells can be connected in series in order to achieve a desired voltage, such as through an electrical wiring connection. Each end of the series connected cells can be attached to a suitable conductor such as a wire or bus bar, to direct the photovoltaically generated current to convenient locations for connection to a device or other system using the generated electric. A convenient means for achieving such series connections is to laser scribe the device to divide the device into a series of cells connected by interconnects. In one particular embodiment, for instance, a laser can be used to scribe the deposited layers of the semiconductor device to divide the device into a plurality of series connected cells.

Methods of manufacturing the devices 10 of FIGS. 1-12 are also encompassed by the present disclosure.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. A thin film photovoltaic device, comprising:
a transparent substrate having a first volumetric thermal expansion coefficient;
a thin film stack comprising a transparent conductive oxide layer, a photovoltaic heterojunction, and back contact layer; and,
a composite encapsulation material on the back contact layer, wherein the composite encapsulation material has a second volumetric thermal expansion coefficient that is within about +/−40% of the first volumetric thermal expansion coefficient of the transparent substrate;
wherein the thin film stack is positioned between the transparent substrate and the composite encapsulation material, and wherein the composite encapsulation material and the transparent substrate are constructed from different materials.

2. The device of claim 1, wherein the second volumetric thermal expansion coefficient of the composite encapsulation material is within about +/−25% of the first volumetric thermal expansion coefficient of the transparent substrate.

3. The device of claim 1, wherein the second volumetric thermal expansion coefficient of the composite encapsulation material is within about +/−10% of the first volumetric thermal expansion coefficient of the transparent substrate.

4. The device of claim 1, wherein the second volumetric thermal expansion coefficient of the composite encapsulation material is about 5% to about 25% of the first volumetric thermal expansion coefficient of the transparent substrate.

5. The device of claim 1, wherein the second volumetric thermal expansion coefficient of the composite encapsulation material is about −5% to about −25% of the first volumetric thermal expansion coefficient of the transparent substrate.

6. The device of claim 1, further comprising:
a back substrate attached to the composite encapsulation material.

7. The device of claim 6, wherein the composite encapsulation material is positioned between the thin film stack and the back substrate.

8. The device of claim 6, wherein the back substrate is positioned between the thin film stack and the composite encapsulation material.

9. The device of claim 6, wherein the composite encapsulation material comprises a web of fibers.

10. The device of claim 1, wherein the composite encapsulation material comprises a film-forming binder.

11. The device of claim 1, wherein the composite encapsulation material defines at least one rib element.

12. The device of claim 1, further comprising:
an adhesive layer positioned between the thin film stack and the composite encapsulation material.

13. The device of claim 1, wherein the transparent substrate comprises a glass that has a thickness of about 0.5 mm to about 2.5 mm.

14. A thin film photovoltaic device, comprising:
a transparent substrate having a first volumetric thermal expansion coefficient and a thickness of about 0.5 mm to about 2.5 mm;
a thin film stack comprising a transparent conductive oxide layer, a photovoltaic heterojunction, and back contact layer; and,
a composite encapsulation material on the back contact layer, wherein the composite encapsulation material has a second volumetric thermal expansion coefficient that is within about +/−3.5 from the first volumetric thermal expansion coefficient of the transparent substrate;
wherein the thin film stack is positioned between the transparent substrate and the composite encapsulation material, and wherein the composite encapsulation material and the transparent substrate are constructed from different materials.

15. The device of claim 14, wherein the second volumetric thermal expansion coefficient of the composite encapsulation material is within about +/−2.0 from the first volumetric thermal expansion coefficient of the transparent substrate.

16. The device of claim 14, further comprising:
a back substrate attached to the composite encapsulation material.

17. The device of claim 16, wherein the composite encapsulation material comprises a web of fibers.

18. The device of claim 14, wherein the composite encapsulation material comprises a film-forming binder.

19. The device of claim 1, further comprising:
an adhesive layer positioned between the thin film stack and the composite encapsulation material.

20. A thin film photovoltaic device, comprising:
a transparent substrate comprising a first material, wherein the transparent substrate has a front thickness of about 0.5 mm to about 2.5 mm defined from a front surface to an inner surface;
a thin film stack comprising a transparent conductive oxide layer, a photovoltaic heterojunction, and back contact layer; and,
a composite encapsulation material laminated to the transparent substrate such that the thin film stack is positioned between the transparent substrate and the composite encapsulation material, wherein the transparent substrate and the composite encapsulation material are constructed from different materials;
wherein the composite encapsulation material has a back thickness and a volumetric thermal expansion coefficient to limit bowing in the transparent substrate upon lamination such that a maximum peak-to-trough distance defined by the front surface of the transparent substrate is about 100% or less than the front thickness.
